(19) United States
(12) Patent Application Publication
(10) Pub. No.: US 2026/0171130 A1
(43) Pub. Date: Jun. 18, 2026

(54) MAGNETIC MEMORY DEVICE

(71) Applicant: Samsung Electronics Co., Ltd., Suwon-si (KR)

(72) Inventors: Dae Shik KIM, Suwon-si (KR); Kyoung Ho KIM, Suwon-si (KR); Ji Hun BYUN, Suwon-si (KR)

(73) Assignee: Samsung Electronics Co., Ltd., Suwon-si (KR)

(21) Appl. No.: 19/352,089

(22) Filed: Oct. 7, 2025

(30) Foreign Application Priority Data
Dec. 16, 2024 (KR) 10-2024-0187007

(51) Int. Cl. G11C 11/16

(52) U.S. Cl. CPC G11C 11/1675; G11C 11/1655; G11C 11/1657; G11C 11/1659

(57) ABSTRACT

Provided is a magnetic memory device. The magnetic memory device includes a memory cell including a first magnetic tunnel junction element, a One-Time-Programmable (OTP) cell including a second magnetic tunnel junction element, a switching element between a first bit line connected to the memory cell and a second bit line connected to the OTP cell, and a peripheral circuit configured to control the switching element to disconnect the first and second bit lines from each other in response to a write voltage being applied to the OTP cell.

### CROSS-REFERENCE TO RELATED APPLICATION

This application claims priority from Korean Patent Application No. 10-2024-0187007 filed on Dec. 16, 2024 in the Korean Intellectual Property Office, and all the benefits accruing therefrom under 35 U.S.C. § 119, the contents of which in its entirety are herein incorporated by reference.

### BACKGROUND

Some example embodiments relate to a magnetic memory device.

As electronic device become faster and less power-consuming, memory devices embedded therein also expects fast read/write operations and low operating voltage. A magnetic memory device is being studied as the memory device that satisfies these requirements. The magnetic memory device is nonvolatile and capable of high-speed operation, and thus is receiving attention as a next-generation memory.

As the magnetic memory device becomes increasingly highly integrated, STT-MRAM which stores therein information using the Spin Transfer Torque (STT) phenomenon, is being studied. The STT-MRAM may store therein information by directly applying current to a magnetic tunnel junction element to induce magnetization reversal. The highly integrated STT-MRAM enables high-speed operation and low-current operation.

In some examples, an OTP (One-Time-Programmable) memory is a nonvolatile memory in which data is permanently maintained upon a single program. The OTP memory is generally used for the purpose of recording specific information only once and allowing the information to be read continuously, and may be used in applications where data stability and security are important. Since the OTP memory may be programmed only once, information therein cannot be changed, thereby ensuring data integrity and stability. The OTP memory is mainly used in applications that expect reliability and security. For example, the OTP memory is used to store information therein; the information may include one or more of digital security tokens, smart cards, keys and passwords, booting codes, and production/manufacturing settings, and may be embedded as a portion of a semiconductor chip therein or may be provided as an independent chip. When the OTP memory is embedded as the portion of the chip therein, the OTP memory may be implemented at low cost and thus may be usefully used without affecting performance of a core logic as long as the OTP is fully compatible with a logic CMOS process.

### SUMMARY

Some example embodiments may provide a magnetic memory device with improved product reliability.

Purposes according to inventive concepts are not limited to the above-mentioned purpose. Other purposes and/or advantages according to inventive concepts that are not mentioned may be understood based on following descriptions, and may be more clearly understood based on embodiments according to the present disclosure. Further, it will be easily understood that the purposes and/or advantages according to some example embodiments may be realized using means shown in the claims and combinations thereof.

A magnetic memory device according to some example embodiments includes a memory cell including a first magnetic tunnel junction element, One-Time-Programmable (OTP) cell including a second magnetic tunnel junction element, a switching element between a first bit line connected to the memory cell and a second bit line connected to the OTP cell, and a peripheral circuit configured to control the switching element to disconnect the first and second bit lines from each other in response to a write voltage being applied to the OTP cell.

Alternatively or additionally magnetic memory device according to some example embodiments includes a memory cell connected to a first bit line and including a first magnetic tunnel junction element, an OTP cell connected to a second bit line and including a second magnetic tunnel junction element, a bit line connection transistor between the first and second bit lines in a first direction in which the first and second bit lines extend, and a peripheral circuit configured to control the bit line connection transistor. The peripheral circuit is configured to control the bit line connection transistor to be turned off in response to a first write voltage applied to the OTP cell, and to control the bit line connection transistor to be turned on in response to a second write voltage being applied to the memory cell.

Alternatively or additionally a magnetic memory device comprising a memory cell and an OTP cell according to some example embodiments includes a first magnetic tunnel junction element connected to a first bit line, and a first cell transistor connecting a first source line and the first magnetic tunnel junction element to each other and connected to a first word line, a second magnetic tunnel junction element connected to a second bit line, a cell array connecting a second source line and the second magnetic tunnel junction element to each other, wherein the cell array includes a second cell transistor, a third cell transistor, and a fourth cell transistor that are connected to a second word line, a third word line, and a fourth word line, respectively, a switching element between the first bit line and the second bit line in a first direction in which the first and second bit lines extend, a first via structure on one side of the switching element and adjacent to the memory cell, a second via structure on another side of the switching element and adjacent to the OTP cell, and a peripheral circuit closer to the OTP cell than to the memory cell in the first direction. The peripheral circuit is configured to control the switching element to electrically disconnect the first and second bit lines from each other in response to a first write operation being performed on the OTP cell.

Alternatively or additionally according to some example embodiments, there is provided a method of operating a magnetic memory device including first and second bit lines connectable to each other, a memory cell connected to the first bit line, and a One-Time Programmable (OTP) cell connected to the second bit line, the method comprising disconnecting the first and second bit lines from each other in response to a write voltage being applied to the OTP cell.

The method may further comprise controlling the write voltage to not be applied to the memory cell.

The method may further comprise applying the write voltage to the OTP cell based on a row address supplied to a row decoder and on a column address supplied to a column decoder.

Specific details of example embodiments are included in the detailed description and drawings.

### BRIEF DESCRIPTION OF DRAWINGS

The above and other aspects and features will become more apparent by describing in detail illustrative embodiments thereof with reference to the attached drawings, in which:

FIG. 1 is an example block diagram of a magnetic memory device according to some example embodiments;

FIG. 2 is an example circuit diagram for illustrating a magnetic memory device according to some example embodiments;

FIG. 3 is an example circuit diagram for illustrating a memory cell according to some example embodiments;

FIG. 4 is an example circuit diagram for illustrating an OTP cell according to some example embodiments;

FIG. 5 is a diagram for illustrating resistances of memory cells and OTP cells according to some example embodiments;

FIG. 6 is an example layout plan view of a magnetic memory device according to some example embodiments;

FIG. 7 is an example cross-sectional view taken along a line A-A′ of FIG. 6;

FIG. 8 is an example cross-sectional view of a magnetic memory device according to some example embodiments;

FIGS. 9 to 11 are example cross-sectional views of a magnetic memory device according to some example embodiments;

FIG. 12 is a diagram for illustrating a cell area and a peripheral circuit area of a magnetic memory device according to some example embodiments;

FIG. 13 is an enlarged view for illustrating an area S of FIG. 12.

### DETAILED DESCRIPTION

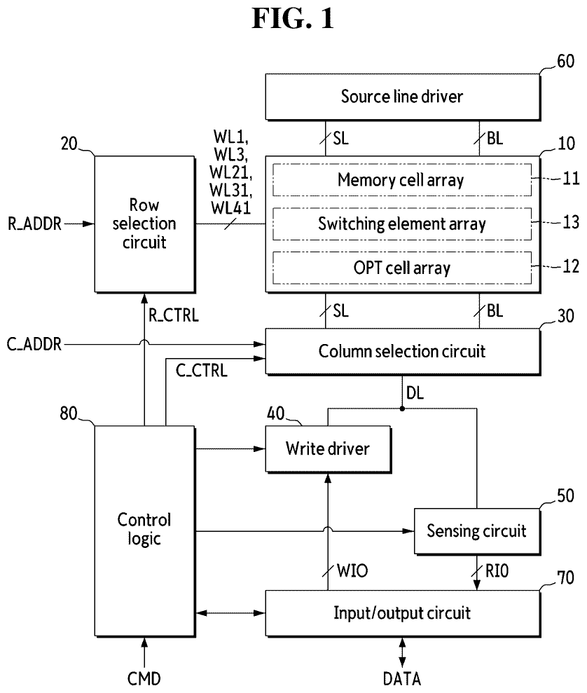

FIG. 1 is an example block diagram of a magnetic memory device according to some example embodiments.

Referring to FIG. 1, the magnetic memory device according to some example embodiments may include a cell array 10, a row selection circuit 20, a column selection circuit 30, a write driver 40, a sensing circuit 50, a source line driver 60, an input/output circuit 70, and a control logic 80.

The cell array 10 may include a plurality of memory blocks. A memory block includes a memory cell array 11, an OTP cell array 12, and a switching element array 13. The memory cell array 11 includes a plurality of memory cells connected to the word lines WL1 and the bit lines BL. The OTP cell array 12 includes a plurality of OTP cells connected to the word lines WL21, WL31, and WL41 and the bit lines BL. The switching element array 13 includes a plurality of switching elements connected to the word line WL3 and the bit lines BL.

The memory cells and the OTP cells may be configured to store data therein. The memory cells and/or the OTP cells may include, for example, a variable resistance element in which a value of stored data is determined according to a resistance value. For example, the memory cells and/or the OTP cells may include a magnetic tunnel junction (MTJ) element.

For example, the memory cells and the OTP cells may include one or more of a resistive RAM (ReRAM), a phase change random access memory (PRAM), a ferroelectric random access memory (FRAM), and the like, or may include a magnetic domain access memory (MRAM) such as a spin-transfer torque random access memory (STT-MRAM), a spin torque transfer magnetization switching RAM (Spin-RAM), a spin motion transfer RAM (SMT-RAM), etc.

The row selection circuit 20 may select (or drive) the word lines WL1, WL21, WL31, and WL41 connected to the memory cell and the OTP cell on which the read operation or a program operation is performed based on the row address R_ADDR and the row control signal R_CTRL. Alternatively or additionally, the row selection circuit 20 may select (or drive) the word line WL3 connected to the switching elements. The row selection circuit 20 may provide the driving voltage VDD received from the control logic 80 to the selected word line WL.

The column selection circuit 30 may select a bit line BL and/or a source line SL connected to a memory cell and the OTP cell on which the read operation or the program operation is performed, based on the column address C_ADDR and the column control signal C_CTRL. The column selection circuit 30 may connect the selected bit line BL and the selected source line SL to the data line DL.

During the program operation, the write driver 40 may drive a program voltage (or a write current) for storing write data in the memory cell and the OTP cell selected by the row selection circuit 20 and the column selection circuit 30. For example, during the program operation, the write driver 40 may store the write data DATA in the selected memory cell by controlling a voltage of the data line DL based on the write data DATA input from the input/output circuit 70 via a write input/output line WIO.

The sensing circuit 50 may detect a signal output through the data line DL during a read operation and may determine values of the data stored in the memory cell and the OTP cell based on the detected signal. The sensing circuit 50 may be connected to the column selection circuit 30 via the data line DL, and may be connected to the input/output circuit 70 via the read input/output line RIO. The sensing circuit 50 may input the sensed read data DATA to the input/output circuit 70 via the read input/output line RIO.

The source line driver 60 may drive the source line SL at a specific voltage level under the control of the control logic 80. For example, the source line driver 60 may receive a voltage for driving the source line SL from the control logic 80.

The input/output circuit 70 may transmit the write data DATA input from an external source to the write driver 40, and may output the read data DATA input from the sensing circuit 50 to an external element.

The control logic 80 may generally control the operations of the magnetic memory device. For example, the control logic 80 may control the row selection circuit 20, the column selection circuit 30, the write driver 40, the sensing circuit 50, the source line driver 60, the input/output circuit 70, etc. In one example, the control logic 80 may operate in response to a command CMD or control signals input from the external source. The command CMD may include a read command, a write command, etc.

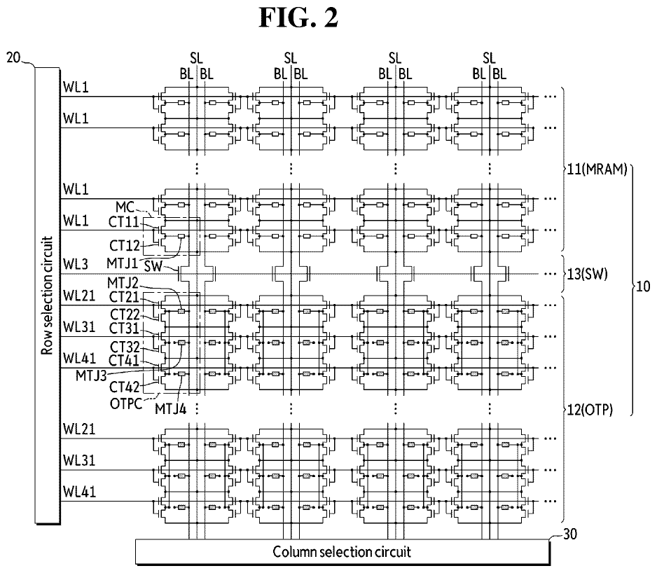

FIG. 2 is an example circuit diagram for illustrating a magnetic memory device according to some example embodiments.

Referring to FIG. 2, the cell array 10 according to some example embodiments may include a memory cell array 11, an OTP cell array 12, and a switching element array 13. The memory cell array 11 includes a plurality of memory cells MC arranged along a row direction and a column direction. The OTP cell array 12 includes a plurality of OTP cells OTPC arranged along a row direction and a column direction. The switching element array 13 includes a plurality of switching elements SW arranged in a column direction.

The plurality of memory cells MC may be connected to the first word lines WL1, the bit lines BL, and the source lines SL. Each of the memory cells MC may include a first magnetic tunnel junction element MTJ1 and a first pair of cell transistors CT11 and CT12.

The memory cell MC may be programmed a plurality of times. The memory cell MC may be switched between two resistance states under an electrical pulse applied to the first magnetic tunnel junction element MTJ1. The memory cell MC may be used as a MRAM.

In some example embodiments, the memory cell MC may have a structure in which a plurality of cell transistors, such as a pair of cell transistors, CT11 and CT12 are connected to one magnetic tunnel junction element MTJ1. For example, the memory cell MC may include two cell transistors CT11 and CT12. The number of cell transistors included in the memory cell MC is not limited thereto and may vary.

One end of the first magnetic tunnel junction element MTJ1 is connected to the bit line BL, and another end of the first magnetic tunnel junction element MTJ1 is connected to one end of a (1-1)st cell transistor CT11 and one end of a (1-2)nd cell transistor CT12. The other end of the (1-1)st cell transistor CT11 and the other end of the (1-2)nd cell transistor CT12 are connected to the source line SL. A gate electrode of the (1-1)st cell transistor CT11 and a gate electrode of the (1-2)nd cell transistor CT12 may be connected to the first word line WL1. The (1-1)st cell transistor CT11 and the (1-2)nd cell transistor CT12 may be turned on or off based on a signal (or voltage) provided through the first word line WL1.

The plurality of OTP cells OTPC may be connected to the second to fourth word lines WL21, WL31, and WL41, the bit lines BL, and the source lines SL. Each OTP cell OTPC may include a second magnetic tunnel junction element MTJ2, a second pair of cell transistors CT21 and CT22, a third magnetic tunnel junction element MTJ3, a third pair of cell transistors CT31 and CT32, a fourth magnetic tunnel junction element MTJ4, and a fourth pair of cell transistors CT41 and CT42.

The OTP cell OTPC may be programmed only once. The programmed second magnetic tunnel junction element MTJ2 may have an irreversible resistance state. The OTP cell OTPC may be used as an OTP.

The OTP cell OTPC according to some example embodiments may have a structure in which a plurality of cell transistors CT21, CT22, CT31, CT32, CT41, and CT42 are connected to one magnetic tunnel junction element MTJ2. For example, the OTP cell OTPC may include six cell transistors CT21, CT22, CT31, CT32, CT41, and CT42. The second pair pf cell transistors CT21 and CT22, the third pair of cell transistors CT31 and CT32, and the fourth pair cell transistors CT41 and CT42 may be connected in parallel with each other. The number of the cell transistors included in the OTP cell OTPC is not limited thereto and may vary.

One end of the second magnetic tunnel junction element MTJ2 is connected to the bit line BL, and another end of the second magnetic tunnel junction element MTJ2 is connected to one end of the (2-1)st cell transistor CT21 and one end of the (2-2)nd cell transistor CT22. Another end of the (2-1)st cell transistor CT21 and another end of the (2-2)nd cell transistor CT22 are connected to the source line SL. A gate electrode of the (2-1)st cell transistor CT 21 and a gate electrode of the (2-2)nd cell transistor CT 22 may be connected to the second word line WL 21. The (2-1)st cell transistor CT21 and the (2-2)nd cell transistor CT22 may be turned on or off based on a signal (or voltage) provided through the second word line WL21.

One end of the third magnetic tunnel junction element MTJ3 is connected to the bit line BL. Another end of the third magnetic tunnel junction element MTJ3 is not connected to one end of the (3-1)st cell transistor CT31 and one end of the (3-2)nd cell transistor CT32, and the third magnetic tunnel junction element MTJ3 is electrically isolated from the third cell transistor CT31 and CT32. One end of the (3-1)st cell transistor CT31 and one end of the (3-2)nd cell transistor CT32 are connected to another end of the second magnetic tunnel junction element MTJ2. Another end of the (3-1)st cell transistor CT31 and another end of the (3-2)nd cell transistor CT32 are connected to the source line SL. A gate electrode of the (3-1)st cell transistor CT 31 and a gate electrode of the (3-2)nd cell transistor CT 32 may be connected to the third word line WL 31. The (3-1)st cell transistor CT31 and the (3-2)nd cell transistor CT32 may be turned on or off based on a signal (or voltage) provided via the third word line WL31.

One end of the fourth magnetic tunnel junction element MTJ4 is connected to the bit line BL, another end of the fourth magnetic tunnel junction element MTJ4 is not connected to one end of the (4-1)st cell transistor CT41 and one end of the (4-2)nd cell transistor CT42, and the fourth magnetic tunnel junction element MTJ4 is electrically isolated from the fourth cell transistor CT41 and CT42. One end of the (4-1)st cell transistor CT41 and one end of the (4-2)nd cell transistor CT42 are connected to another end of the second magnetic tunnel junction element MTJ2. Another end of the (4-1)st cell transistor CT41 and another end of the (4-2)nd cell transistor CT42 are connected to the source line SL. A gate electrode of the (4-1)st cell transistor CT 41 and a gate electrode of the (4-2)nd cell transistor CT 42 may be connected to the fourth word line WL 41. The (4-1)st cell transistor CT41 and the (4-2)nd cell transistor CT42 may be turned on or off based on a signal (or voltage) provided via the fourth word line WL41.

Each of the third and fourth magnetic tunnel junction elements MTJ3 and MTJ4 may act as a dummy magnetic tunnel junction element. Each of the third and fourth magnetic tunnel junction elements MTJ3 and MTJ4 may be an unused magnetic tunnel junction element.

In the cell array 10, the combination of the second magnetic tunnel junction element MTJ2 and the second cell transistor CT21 and CT22, the combination of the third magnetic tunnel junction element MTJ3 and the third cell transistor CT31 and CT32, and the combination of the fourth magnetic tunnel junction element MTJ4 and the fourth cell transistor CT41 and CT42 of the OTP cell OTPC may be arranged such that each of the combination of the second magnetic tunnel junction element MTJ2 and the second cell transistor CT21 and CT22, the combination of the third magnetic tunnel junction element MTJ3 and the third cell transistor CT31 and CT32, and the combination of the fourth magnetic tunnel junction element MTJ4 and the fourth cell transistor CT41 and CT42 of the OTP cell OTPC has a repetition periodicity equal to a repetition periodicity of the combination of the first magnetic tunnel junction element MTJ1 and the first cell transistor CT11 and CT12 of the memory cell MC.

Each of the first to fourth cell transistors CT11, CT12, CT21, CT22, CT31, CT32, CT41, and CT42 may include, for example, at least one of a diode, a PNP bipolar transistor, a NPN bipolar transistor, a NMOS field effect transistor, and a PMOS field effect transistor. Each of the first to fourth cell transistors CT11, CT12, CT21, CT22, CT31, CT32, CT41, and CT42 may include the same, or different, ones of a diode, a PNP bipolar transistor, an NPN bipolar transistor, an NMOS field effect transistor, and a PMOS field effect transistor; example embodiments are not limited thereto.

In some example embodiments, the memory cells MC constituting (or included in) one column and the memory cells MC constituting (or included in) another column may share one source line SL. The OTP cells OTPC constituting (or included in) one column and the OTP cells OTPC constituting (or included in) another column may share one source line SL.

The cell array 10 may be electrically connected to a peripheral circuit. The peripheral circuit may include, for example, the row selection circuit 2, the column selection circuit 30, the write driver 40, the sensing circuit 50, the source line driver 60, the input/output circuit 70, the control logic 80, etc. of FIG. 1. The memory cells MC and the OTP cells OTP may be electrically connected to the peripheral circuit. For example, the memory cells MC and the OTP cells OTP may share the peripheral circuit.

In some example embodiments, the OTP cells OTPC may be connected to a specific word line (e.g., one or more of the second to fourth word lines WL21, WL31, WL41).

The memory cells MC connected to the first word lines WL1 may be disposed in the memory cell array 11, and the OTP cells OTPC connected to the second word lines WL21 and the third word lines WL31 and the fourth word lines WL41 may be disposed in the OTP cell array 12. Only the memory cells MC may be connected to the first word line WL1, and only the OTP cells OTPC may be connected to the second to fourth word lines WL21, WL31, and WL41. The memory cells MC and the OTP cells OTPC may be connected to one bit line BL.

The arrangement of the memory cell array 11 and the OTP cell array 12 in the cell array 10 may vary. For example, the OTP cell array 12 may be disposed around the memory cell array 11.

The plurality of switching elements SW may be connected to the fifth word lines WL3, the bit lines BL, and the source lines SL. The switching elements SW may be disposed between the bit line BL connected to the memory cell MC and the bit line BL connected to the OTP cell OTPC.

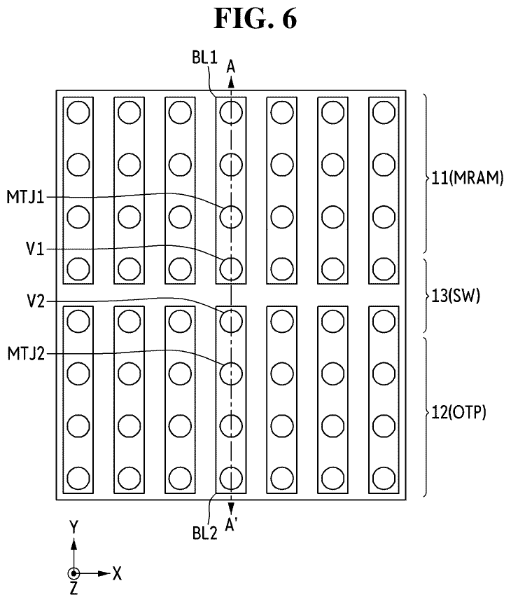

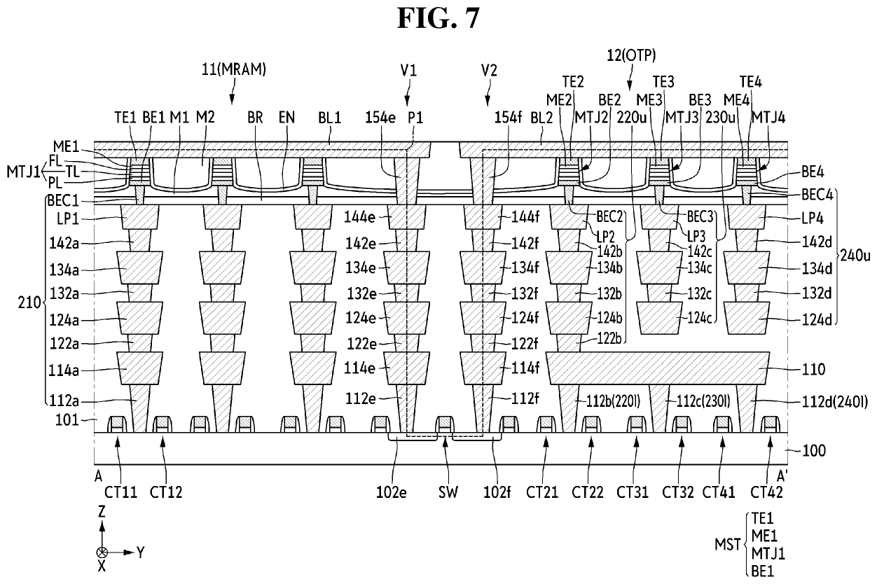

As will be described later, it may be understood that when the switching element SW is turned on such that the switching element SW is electrically connected to each of the first bit line BL1 (see FIGS. 6 and 7) and the second bit line BL2 (see FIGS. 6 and 7), the memory cell MC and the OTP cell OTPC sharing one bit line BL are electrically connected to each other.

The number of switching elements SW included in the switching element array 13 is not limited to what is shown and may vary.

Alternatively or additionally, in some example embodiments there may be a number of redundant rows and/or columns of memory cells MC and/or OTP cells OTPC. The redundant rows and/or columns of memory cells MC and/or OTP cells OTPC may be used in the event that one or more cells on one or more rows and/or columns of memory cells MC and/or OTP cells OTPC are defective, or deemed defective. Example embodiments are not limited thereto.

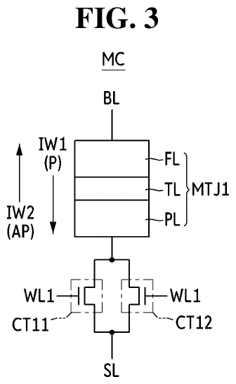

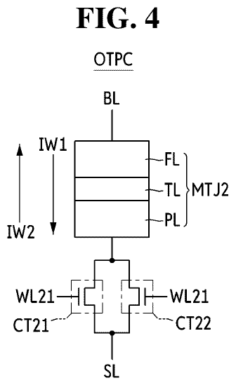

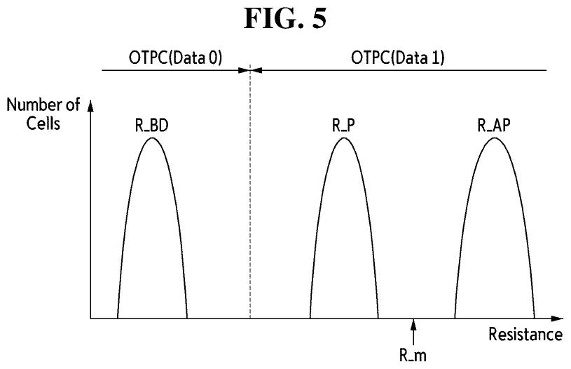

FIG. 3 is an example circuit diagram for illustrating a memory cell according to some example embodiments. FIG. 4 is an example circuit diagram for illustrating an OTP cell according to some example embodiments. FIG. 5 is a diagram for illustrating resistances of memory cells and OTP cells according to some example embodiments.

Referring to FIGS. 3 and 5, the first magnetic tunnel junction element MTJ1 may include a pinned layer PL, a tunnel layer TL, and a free layer FL. The tunnel layer TL may be interposed between (e.g., directly or indirectly interposed between) the pinned layer PL and the free layer FL.

The pinned layer PL may have a fixed magnetization direction regardless of the external magnetic field, and the free layer FL may have a magnetization direction that may be changed to be parallel or anti-parallel to the magnetization direction of the pinned layer PL.

The first magnetic tunnel junction element MTJ1 may store data in the memory cell MC using a difference in an electrical resistance according to the magnetization direction of the pinned layer PL and the magnetization direction of the free layer FL.

For a write operation of the memory cell MC, a turn-on voltage may be applied to the first word line WL1, and a write voltage may be applied across the first magnetic tunnel junction element MTJ1. A first write current IW1 or a second write current IW2 may flow through the first magnetic tunnel junction element MTJ1 according to a direction of the write voltage applied across the first magnetic tunnel junction element MTJ1.

For example, when a relatively high level voltage (e.g., a write voltage) is applied to the bit line BL and a relatively low voltage (e.g., a ground voltage) is applied to the source line SL, the first write current IW1 flowing from the bit line BL to the source line SL may be provided to the first magnetic tunnel junction element MTJ1. In this case, electrons having the same spin direction as that of the pinned layer PL may tunnel through the tunnel layer TL to apply torque to the free layer FL. Accordingly, the first magnetic tunnel junction element MTJ1 may be in a parallel state P in which the magnetization direction of the free layer FL is parallel to the magnetization direction of the pinned layer PL, and the first magnetic tunnel junction element MTJ1 may have a first resistance value R_P and store therein data 0. For example, the data corresponding to the parallel state P may be written in the memory cell MC using the first write current IW1.

When a relatively high level voltage (e.g., the write voltage) is applied to the source line SL and a relatively low voltage (e.g., a ground voltage) is applied to the bit line BL, the second write current IW2 flowing from the source line SL to the bit line BL may be provided to the first magnetic tunnel junction element MTJ1. In this case, electrons having a spin direction opposite to that of the pinned layer PL may not tunnel through the tunnel layer TL and may be reflected to the free layer FL to apply a torque to the free layer FL. Accordingly, the first magnetic tunnel junction element MTJ1 may be changed to the antiparallel state AP in which the magnetization direction of the free layer FL may be antiparallel to the magnetization direction of the pinned layer PL, and the first magnetic tunnel junction element MTJ1 may have a second resistance value R_AP and may store data 1 therein. The second resistance value R_AP may be greater than the first resistance value R_P. That is, the data corresponding to the anti-parallel state AP may be written in the memory cell MC using the second write current IW2.

For example, the memory cell MC may have the first resistance value R_P or the second resistance value R_AP based on the direction of each of the write currents IW1 and IW2 flowing through the first magnetic tunnel junction element MTJ1, and thus may be implemented as a memory cell which is programmable a plurality of times.

A reference resistance value R_m for a read operation of the memory cell MC may be determined. The reference resistance value R_m may have a value between the first resistance value R_P and the second resistance value R_AP.

Although it is illustrated that the free layer FL is connected to the bit line BL and the pinned layer PL is connected to the first cell transistor CT11 and CT12, example embodiments are not limited thereto. The pinned layer PL may be connected to the bit line BL and the free layer FL may be connected to the first cell transistor CT11 and CT12, unlike the illustrated case.

In some example embodiments, each of the pinned layer PL and the free layer FL may have a magnetization easy axis in a direction perpendicular to an interface between the pinned layer PL and the free layer FL.

Each of the pinned layer PL and the free layer FL may include at least one of a perpendicular magnetic material (e.g., one or more of CoFeTb, CoFeGd, and CoFeDy), a perpendicular magnetic material having a L10 structure, a CoPt having a hexagonal close packed lattice structure, and a perpendicular magnetic structure. The perpendicular magnetic material having the L10 structure may include, for example, FePt having a L10 structure, FePd having a L10 structure, CoPd having a L10 structure, CoPt having a L10 structure, etc. The perpendicular magnetic structure may include magnetic layers and non-magnetic layers that are alternately and repeatedly stacked on top of each other. For example, the perpendicular magnetic structure may include (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n is the number of stacks).

In some example embodiments, each of the pinned layer PL and the free layer FL may have a magnetization easy axis in a direction horizontal to an interface between the pinned layer PL and the free layer FL.

Each of the pinned layer PL and the free layer FL may include a ferromagnetic material. In some example embodiments, the pinned layer PL may further include an antiferromagnetic material for fixing the magnetization direction of the ferromagnetic material. For example, the ferromagnetic material may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. For example, the antiferromagnetic material may include at least one of PtMn, IrMn, MnO, MnS, MnTe, MnF2, FeCl2, FeO, CoCl2, CoO, NiCl2, NiO, and Cr, or at least one selected from a precious metal. The precious metal may include ruthenium (Ru), rhodium (Rh), palladium (Pd), osmium (Os), iridium (Ir), platinum (Pt), gold (Au), or silver (Ag). The free layer FL may be composed of a plurality of layers.

The tunnel layer TL may include, for example, at least one selected from oxides of magnesium (Mg), titanium (Ti), aluminum (Al), magnesium-zinc (MgZn) and magnesium-boron (MgB), and nitrides of titanium (Ti) and vanadium (V).

Referring to FIGS. 4 and 5, the OTP cell OTPC may have a structure similar to that of the memory cell MC. For reference, in FIG. 4, the third cell transistors CT31 and CT32 connected to the third word line WL31 and the fourth cell transistors CT41 and CT42 connected to the fourth word line WL41 are omitted.

The second magnetic tunnel junction element MTJ2 may include a pinned layer PL, a tunnel layer TL, and a free layer FL. The tunnel layer TL may be interposed between (e.g., directly or indirectly interposed between) the pinned layer PL and the free layer FL. The pinned layer PL, the tunnel layer TL, and the free layer FL of the second magnetic tunnel junction element MTJ 2 may be made of the same materials as those of the pinned layer PL, the tunnel layer TL, and the free layer FL of the first magnetic tunnel junction element MTJ1, respectively. In some example embodiments, pinned layer PL, the tunnel layer TL, and the free layer FL of the second magnetic tunnel junction element MTJ 2 may be formed at the same time as the formation of the respective pinned layer PL, the tunnel layer TL, and the free layer FL of the first magnetic tunnel junction element MTJ1; example embodiments are not limited thereto. Some of the OTP cells OTPC may be in a state in which the second magnetic tunnel junction element MTJ 2 is in an insulation-broken down state, and each of the rest of the OTPC cells OTPC may be in a state in which the second magnetic tunnel junction element MTJ 2 is not in an insulation-broken down state.

In each of some of the OTP cells OTPC, a breakdown voltage may be applied across the second magnetic tunnel junction element MTJ 2 via one program operation, and the tunnel layer TL of the second magnetic tunnel junction element MTJ 2 may be insulation-broken down. Each of some of the OTP cells OTPC may have an irreversible resistance state. A breakdown current may flow through the second magnetic tunnel junction element MTJ 2 under the breakdown voltage. The breakdown current may be greater than each of the first and second write currents IW1 and IW2. The second magnetic tunnel junction element MTJ2 that is insulation-broken down may be in a short-circuited state. The second magnetic tunnel junction element MTJ2 that is insulation-broken down may have a third resistance value R_BD and may store data 0 therein. The second magnetic tunnel junction element MTJ2 that is not insulation-broken down may have a resistance value greater than the third resistance value R_BD and store data 1 therein. The second magnetic tunnel junction element MTJ2 which is not insulation-broken down may be in the parallel state P or the anti-parallel state AP.

For example, the OTP cell OTPC may be programmed only once, may have a state in which the tunnel layer TL is in an insulation-broken down state or in a state in which the tunnel layer TL is not in an insulation-broken down state, and may be used as an OTP.

As described above, for a write operation of the memory cell MC, a high level voltage (e.g., a write voltage) may be applied to the bit line BL and a low voltage (e.g., a ground voltage) may be applied to the source line SL, or a high level voltage (e.g., the write voltage) may be applied to the source line SL and a low voltage (e.g., a ground voltage) may be applied to the bit line BL. The write voltage is applied to the bit line BL, the first magnetic tunnel junction element MTJ1, the cell transistor CT11 and CT12, the source line SL, etc. in a divided manner.

Since the breakdown voltage should be applied across the second magnetic tunnel junction element MTJ 2 for the write operation of the OTP cell OTPC, the magnitude of the write voltage applied for the write operation of the OTP cell OTPC is to be greater than the magnitude of the write voltage applied for the write operation of the memory cell MC.

For example, when the memory cell MC and the OTP cell OTPC share the bit line BL, the source line SL, and the peripheral circuit with each other, a high-level write voltage may be applied to the cell transistor of the memory cell MC on which a program operation is not performed.

In this case, the intensity of the current flowing through the memory cell MC becomes excessively large, and thus the performance of the device may be deteriorated. Furthermore, the sizes of other components required to apply the current may be increased, and thus the overall size of the device may be excessively increased.

The magnetic memory device according to some example embodiments may include a switching element SW disposed between and connected to the bit line BL connected to the memory cell MC and the bit line BL connected to the OTP cell OTPC. In some example embodiments, the bit line BL connected to the memory cell MC may be referred to as a first bit line (BL1 of FIGS. 6 and 7), and the bit line BL connected to the OTP cell OTPC may be referred to as a second bit line (BL2 of FIGS. 6 and 7).

The switching element SW may be disposed between and connected to the first and second bit lines BL1 and BL2 (see FIGS. 6 and 7) in a direction (Y direction of FIGS. 6 and 7) in which the first and second bit lines BL1 and BL2 (see FIGS. 6 and 7) extend. In some example embodiments, the switching element SW may be referred to as a bit line connection transistor.

When a write voltage is applied to the OTP cell OTPC, the peripheral circuit may control the switching element SW to disconnect the first and second bit lines BL1 and BL2 (see FIGS. 6 and 7) from each other. When a write voltage is applied to the OTP cell OTPC, the peripheral circuit may control the write voltage not to be applied to the memory cell MC.

For example, when a write operation of the OTP cell OTPC is performed, the peripheral circuit may control the switching element SW not to be connected to the first and second bit lines BL1 and BL2 (see FIGS. 6 and 7). In some example embodiments, when a write voltage is applied to the OTP cell OTPC, the peripheral circuit may control the switching element SW to be turned off.

For example, the OTP cell OTPC may correspond to the second word line WL21, and the switching element SW may correspond to the fifth word line WL3. When a write voltage is applied to the OTP cell OTPC, the peripheral circuit may activate a driving signal for driving the second word line WL21 and may deactivate a driving signal for driving the fifth word line WL3. That is, the peripheral circuit may select the second word line WL21 but may not select the fifth word line WL3 in order to apply the write voltage to the OTP cell OTPC.

Accordingly, the fifth word line WL3 may not be driven and the switching element SW may be turned off. As the switching element SW is turned off, a high voltage may be prevented from being applied to the memory cell MC.

For example, when the write operation of the OTP cell OTPC is performed, the write voltage applied to the OTP cell OTPC is applied only to the switching element SW, thereby preventing an excessive current from flowing through the bit line BL to the memory cell MC. For example, the write voltage applied to the OTP cell OTPC may be applied only to a drain area of the switching element SW. However, example embodiments are not limited thereto.

When the write operation of the OTP cell OTPC is not performed, for example, when the read operation of the OTP cell OTPC is performed, the write operation of the memory cell MC is performed, or the read operation of the memory cell MC is performed, the peripheral circuit may control the switching element SW to connect the first and second bit lines BL1 and BL2 of FIGS. 6 and 7 to each other. In some example embodiments, when a read operation of the OTP cell OTPC is performed, a write operation of the memory cell MC is performed, or a read operation of the memory cell MC is performed, the peripheral circuit may control the switching element SW to be turned on.

For example, when a write voltage is applied to the memory cell MC, the peripheral circuit may control the switching element SW to electrically connect the first and second bit lines BL1 and BL2 (see FIGS. 6 and 7) to each other. In some example embodiments, when a write voltage is applied to the memory cell MC, the peripheral circuit may control the switching element SW to be turned on.

FIG. 6 is an example layout plan view of a magnetic memory device according to some example embodiments. FIG. 7 is an example cross-sectional view taken along a line A-A′ of FIG. 6.

FIG. 7 is an example cross-sectional view of a portion including three memory cells MC connected to one bit line in FIG. 2 and a portion including one OTP cell OTPC connected to one bit line in FIG. 2. For convenience of illustration, the source line SL of FIG. 2 is omitted in FIG. 7.

Referring to FIGS. 6 and 7, the magnetic memory device according to some example embodiments may include a substrate 100, first to fourth cell transistors CT11, CT12, CT21, CT22, CT31, CT32, CT41, and CT42, an insulating film 101, a wiring structure 210, first to third lower wiring structures 220l, 230l, and 240l, first to third upper wiring structures 220u, 230u, and 240u, first to fourth lower electrodes BE1, BE2, BE3, and BE4, first to fourth magnetic tunnel junction elements MTJ1, MTJ2, MTJ3, and MTJ4, first to fourth upper electrodes TE1, TE2, TE3, and TE4, first and second bit lines BL1 and BL2, a first via structure V1, and a second via structure V2. The bit line BL of FIG. 2 may include the first bit line BL1 connected to the memory cell MC and the second bit line BL2 connected to the OTP cell OTPC.

The memory cells MC may be disposed in the memory cell array 11. Each memory cell MC may include the first magnetic tunnel junction element MTJ1. In the OTP cell array 12, the OTP cells OTPC may be disposed. Each OTP cell OTPC may include the second to fourth magnetic tunnel junction elements MTJ2, MTJ3, and MTJ4.

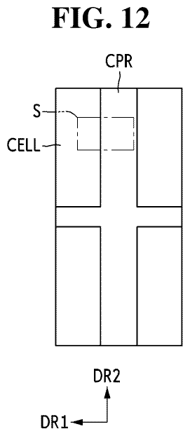

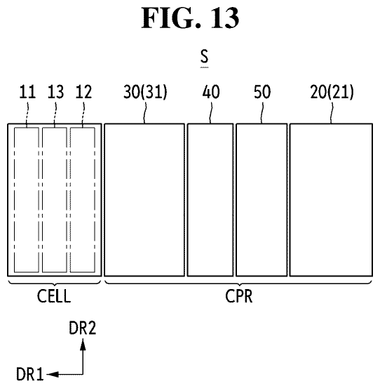

The switch element SW may be disposed in the switch element array 13. The first via structure V1 may be disposed between the switch element SW and the memory cell MC. The second via structure V2 may be disposed between the switch element SW and the OTP cell OTPC. That is, the first and second via structures V1 and V2 may be disposed not in the peripheral circuit area CPR of FIGS. 12 and 13 to be described later but in the cell area CELL of FIGS. 12 and 13.

Each memory cell MC may include the first cell transistor CT11 and CT12, the wiring structure 210, the first lower electrode BE1, the first magnetic tunnel junction element MTJ1, and the first upper electrode TE1.

Each OTP cell OTPC may include the second to fourth cell transistors CT21, CT22, CT31, CT32, CT41, and CT42, the connection wiring 110, the first to third lower wiring structures 220l, 230l, and 240l, the first to third upper wiring structures 220u, 230u, and 240u, the second to fourth lower electrodes BE2, BE3, and BE4, the second to fourth magnetic tunnel junction elements MTJ2, MTJ3, and MTJ4, and the second to fourth upper electrodes TE2, TE3, and TE4.

The substrate 100 may be or may include, for example, one or more of a silicon substrate, a gallium arsenide substrate, a silicon germanium substrate, a ceramic substrate, a quartz substrate, a glass substrate for display, or the like, or may be a semiconductor on insulator (SOI) substrate. However, example embodiments are not limited thereto.

The substrate 100 may extend in first and second horizontal directions X and Y intersecting each other. A third direction Z may mean a height direction perpendicular to each of the first and second horizontal directions X and Y.

The first to fourth cell transistors CT11, CT12, CT21, CT22, CT31, CT32, CT41, and CT42 may be formed on the substrate 100. A first impurity area (not shown) may be formed in the substrate 100 and at each of both opposing sides of the first cell transistor CT11 and CT12. The first impurity area may be formed with an implantation process; example embodiments are not limited thereto. The first impurity area (not shown) may be provided as a source area or a drain area of the first cell transistor CT11 and CT12. A second impurity area (not shown) may be formed in the substrate 100 and at each of both opposing sides of each of the second to fourth cell transistors CT21, CT22, CT31, CT32, CT41 and CT42. The second impurity area may be formed with an implantation process; example embodiments are not limited thereto. The second impurity area (not shown) may be provided as a source area or a drain area of each of the second to fourth cell transistors CT21, CT22, CT31, CT32, CT41, and CT42. Each of the first impurity area (not shown) and the second impurity area (not shown) may include an N-type and/or P-type impurity, such as an N-type impurity at a first concentration and a P-type impurity at a second concentration much greater than or much less than the first concentration.

The switching element SW may be implemented using cell transistors of the memory cells MC and the OTP cells OTPC. A third impurity area 102e and a fourth impurity area 102f may be formed in the substrate 100 and respectively at both opposing sides of the switching element SW. Each of the third impurity area 102e and the fourth impurity area 102f may be provided as a source area or a drain area of the switching element SW. Each of the third impurity area 102e and the fourth impurity area 102f may include an N-type or P-type impurity, such as an N-type impurity at a first concentration and a P-type impurity at a second concentration much greater than or much less than the first concentration.

The insulating film 101 may be formed on the substrate 100. The insulating film 101 may cover the first to fourth cell transistors CT11, CT12, CT21, CT22, CT31, CT32, CT41, and CT42 and the switching element SW. At least a portion of the wiring structure 210, the first to third lower wiring structures 220l, 230l, and 240l, the connection wiring 110, at least a portion of each of the first to third upper wiring structures 220u, 230u, and 240u, at least a portion of the first via structure V1, and at least a portion of the second via structure V2 may be formed in the insulating film 101. The insulating film 101 may include, for example, silicon oxide, silicon oxynitride, or the like. Although not shown in detail, the insulating film 101 may have a multilayer structure.

The first to fourth magnetic tunnel junction elements MTJ1, MTJ2, MTJ3, and MTJ4 may be formed on the substrate 100. The first to fourth magnetic tunnel junction elements MTJ1, MTJ2, MTJ3, and MTJ4 may be formed at substantially the same vertical level from the substrate 100. In some example embodiments, each of the second to fourth magnetic tunnel junction elements MTJ2, MTJ3, and MTJ4 may have substantially the same size and structure as those of the first magnetic tunnel junction element MTJ1.

The wiring structure 210, the first to third lower wiring structures 220l, 230l, and 240l, the first to third upper wiring structures 220u, 230u, and 240u, the first via structure V1, and the second via structure V2 may be formed on the substrate 100.

The wiring structure 210 may connect the substrate 100 and the first magnetic tunnel junction element MTJ1 to each other. The wiring structure 210 may include a (1-1)st via 112a, a (1-1)st wiring 114a, a (2-1)st via 122a, a (2-1)st wiring 124a, a (3-1)st via 132a, a (3-1)st wiring 134a, a (4-1)st via 142a, a first landing pad LP1, and a first lower electrode contact BEC1 which are sequentially stacked on the substrate 100. The (1-1)st via 112a may be connected to the first impurity area (not shown) between the first cell transistors CT11 and CT12. The (2-1)st via 122a may connect the (1-1)st wiring 114a and the (2-1)st wiring 124a to each other. The (3-1)st via 132a may connect the (2-1)st wiring 124a and the (3-1)st wiring 134a to each other. The (4-1)st via 142a may connect the (3-1)st wiring 134a and the first landing pad LP1 to each other. The first lower electrode contact BEC1 may connect the first landing pad LP1 and the first magnetic junction element MTJ1 to each other.

In some example embodiments, the magnetic memory device may include a memory structure MST. The memory structure MST may be disposed on the first to fourth lower electrode contacts BEC1, BEC2, BEC3, and BEC4. For example, the memory structure MST may include the first lower electrode BE1, the first magnetic tunnel junction element MTJ1, a first intermediate electrode ME1, the first upper electrode TE1, etc. In this regard, the first lower electrode BE1, the first magnetic tunnel junction element MTJ1, the first intermediate electrode ME1, and the first upper electrode TE1 may be sequentially stacked from an upper surface of the first lower electrode contact BEC1.

The memory structure MST may have an inclined sidewall; example embodiments are not limited thereto. For example, in some example embodiments, an area size of a lower surface of the memory structure MST may be greater than an area size of an upper surface thereof. Alternatively or additionally in some example embodiments, the area size of the lower surface of the memory structure MST may be greater than or equal to an area size of the upper surface of the first lower electrode contact BEC1.

Each of the first to fourth magnetic tunnel junction elements MTJ1, MTJ2, MTJ3, and MTJ4 may include a first magnetic pattern PL, a tunnel barrier pattern TL, and a second magnetic pattern FL. The tunnel barrier pattern TL may be interposed between the first magnetic pattern PL and the second magnetic pattern FL.

One of the first magnetic pattern PL and the second magnetic pattern FL may be a reference layer having a fixed magnetization direction regardless of an external magnetic field, and the other of the first magnetic pattern PL and the second magnetic pattern FL may be a free layer whose the magnetization direction is variable between two stable magnetization directions. For example, the first magnetic pattern PL may be a reference layer having a fixed magnetization direction, and the second magnetic pattern FL may be a free layer having a variable magnetization direction. In another example, the first magnetic pattern PL may be a free layer, and the second magnetic pattern FL may be a reference layer.

In some example embodiments, each of the first magnetic pattern PL and the second magnetic pattern FL may have perpendicular magnetic anisotropy (PMA). Each of the first magnetic pattern PL and the second magnetic pattern FL may have a magnetization easy axis in a vertical direction (a direction perpendicular to the upper surface of the substrate 100).

Each of the first magnetic pattern PL and the second magnetic pattern FL may include at least one of a perpendicular magnetic material (e.g., CoFeTb, CoFeGd, and CoFeDy), a perpendicular magnetic material having a L10 structure, a CoPt having a hexagonal close packed lattice structure, and a perpendicular magnetic structure. The perpendicular magnetic material having the L10 structure may include, for example, FePt having a L10 structure, FePd having a L10 structure, CoPd having a L10 structure, CoPt having a L10 structure, or the like. The perpendicular magnetic structure may include magnetic layers and non-magnetic layers that are alternately and repeatedly stacked on top of each other. For example, the perpendicular magnetic structure may include (Co/Pt)n, (CoFe/Pt)n, (CoFe/Pd)n, (Co/Pd)n, (Co/Ni)n, (CoNi/Pt)n, (CoCr/Pt)n or (CoCr/Pd)n (where n is the number of stacks).

In some example embodiments, each of the first magnetic pattern PL and the second magnetic pattern FL may have in-plane magnetic anisotropy (IMA). Each of the first magnetic pattern PL and the second magnetic pattern FL may have a magnetization easy axis in a horizontal direction (a direction parallel to the upper surface of the substrate 100).

Each of the first magnetic pattern PL and the second magnetic pattern FL having the in-plane magnetic anisotropy IMA may include a ferromagnetic material. In some example embodiments, the magnetic pattern constituting the reference layer among the first magnetic pattern PL and the second magnetic pattern FL may further include an antiferromagnetic material for fixing the magnetization direction of the ferromagnetic material. For example, the ferromagnetic material of the reference layer may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. For example, the antiferromagnetic material of the reference layer may include at least one of PtMn, IrMn, MnO, MnS, MnTe, MnF2, FeCl2, FeO, CoCl2, CoO, NiCl2, NiO, and Cr, or at least one selected from a precious metal. The precious metal may include one or more of ruthenium (Ru), rhodium (Rh), palladium (Pd), osmium (Os), iridium (Ir), platinum (Pt), gold (Au), or silver (Ag). The free layer FL may be composed of a plurality of layers. For example, the ferromagnetic material of the free layer may include at least one of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO, and Y3Fe5O12. The magnetic pattern MP as a free layer may be composed of a plurality of layers.

The tunnel barrier pattern TL may include, for example, at least one selected from oxides of magnesium (Mg), titanium (Ti), aluminum (Al), magnesium-zinc (MgZn), and magnesium-boron (MgB), and nitrides of titanium (Ti) and vanadium (V).

The first magnetic tunnel junction element MTJ1 may store data in each of the memory cells MC based on a difference in the electrical resistance according to the magnetization direction of the first magnetic pattern PL and the magnetization direction of the second magnetic pattern FL.

For example, when the magnetization direction of the first magnetic pattern PL and the magnetization direction of the second magnetic pattern FL are parallel to each other, the first magnetic tunnel junction element MTJ1 has a low resistance value. In this case, the data may be stored and read as ‘0’. On the contrary, when the magnetization direction of the first magnetic pattern PL and the magnetization direction of the second magnetic pattern FL are antiparallel to each other, the first magnetic tunnel junction element MTJ1 has a high resistance value. In this case, the data may be stored and read as ‘1’. In another example, when the magnetization direction of the first magnetic pattern PL and the magnetization direction of the second magnetic pattern FL are parallel to each other, the data of the first magnetic tunnel junction element MTJ1 may be stored and read as “1”. When the magnetization direction of the first magnetic pattern PL and the magnetization direction of the second magnetic pattern FL are anti-parallel to each other, the data of the first magnetic tunnel junction element MTJ1 may be stored and read as “0”.

The second magnetic tunnel junction element MTJ2 may have an irreversible resistance state formed by applying a break-down voltage across the first magnetic pattern PL and the second magnetic pattern FL through one programming operation to insulation-breakdown the tunnel barrier pattern TL between the first magnetic pattern PL and the second magnetic pattern FL. The second magnetic tunnel junction element MTJ2 that is insulation-broken down may be in a short-circuited state. The insulation-broken down second magnetic tunnel junction element MTJ2 has a low resistance value, and in this case, data DATA may be stored and read as ‘0’. The second magnetic tunnel junction element MTJ2 that is not insulation-broken down has a high resistance value, and in this case, data may be stored and read as ‘1’.

The cell array 10 of the magnetic memory device according to some example embodiments includes memory cells MC used as MRAM and OTP cells OTPC used as OTP. For example, since the memory cells MC and the OTP cells OTP are implemented in one cell array 10 without a separate OTP memory, a highly integrated magnetic memory device may be provided.

During a write operation of the OTP cell OTP, a breakdown voltage is applied to the second magnetic junction tunnel MTJ2 to insulation-break down the tunnel barrier pattern TL of the second magnetic junction tunnel element MTJ2. The breakdown voltage has a higher value than the write voltage VWR applied to the first magnetic junction tunnel MTJ1 during the write operation of the memory cell MC. As a result, the stress may be applied to the memory cell MC.

In some examples, in the memory device according to some example embodiments, since the OTP cell OTPC includes the second to fourth cell transistors CT21, CT22, CT31, CT32, CT41, and CT42 connected in parallel with each other, a greater voltage may be applied across the second magnetic junction tunnel MTJ2. Therefore, even when the write voltage applied to the OTP cell OTPC is not greatly high, the insulation breakdown of the tunnel barrier pattern TL of the second magnetic junction tunnel MTJ2 may occur more easily. Alternatively or additionally, the stress of the memory unit cell MC due to the write voltage applied to the OTP cell OTPC may be improved and/or reduced.

The first lower electrode BE1 may be formed on the first lower electrode contact BEC1. The first magnetic junction element MTJ1 may be formed on the first lower electrode BE1. The first intermediate electrode ME1 may be formed on the first magnetic junction element MTJ1. The first upper electrode TE1 may be formed on the first intermediate electrode ME1. The first upper electrode TE1 may be connected to the first magnetic tunnel junction element MTJ1.

The first lower electrode BE1 may include a metal such as one or more of titanium, tantalum, or the like, and/or a metal nitride such as one or more of titanium nitride, tantalum nitride, or the like. The first intermediate electrode ME1 may include at least one of a metal such as titanium, tantalum, or the like, or a metal nitride such as titanium nitride, tantalum nitride, or the like. The first upper electrode TE1 may include at least one of a metal such as titanium or tantalum, or a metal nitride such as titanium nitride or tantalum nitride. Alternatively, the first upper electrode TE1 may include tungsten, copper, platinum, nickel, silver, gold, or the like.

The first bit line BL1 may be formed on the first upper electrode TE1. The first bit line BL1 may be connected to the first upper electrode TE1. The first magnetic tunnel junction element MTJ1 may be electrically connected to the first cell transistor CT11 and CT12 via the wiring structure 210, and may be electrically connected to the first bit line BL1 via the first upper electrode TE1.

The connection wiring 110 may be disposed on the substrate 100. In some example embodiments, the connection wiring 110 may be disposed at the lowest metal level among the wirings. The connection wiring 110 may be a wiring closest to the substrate 100. The second to fourth cell transistors CT21, CT22, CT31, CT32, CT41, and CT42 may be electrically connected to each other via the connection wiring 110 at the metal-level closest to the substrate 100. The connection wiring 110 may be positioned at the same vertical level from the substrate 100 as a vertical level of the (1-1)st wiring 114a. In some examples, the wirings disposed at the same metal level as that of the (1-1)st wiring 114a and disposed respectively under the second to fourth magnetic tunnel junction elements MT2, MTJ3, and MT4 may be directly connected to each other.

The third and fourth magnetic tunnel junction elements MTJ3 and MTJ4 may be isolated from the connection wiring 110 while being positioned at a higher metal level than that of the connection wiring 110. In some example embodiments, between each of the third and fourth magnetic tunnel junction elements MTJ3 and MTJ4 and the connection wiring 110, a via having the same metal level as that of a via in direct contact with the connection wiring 110 may be omitted. For example, between the third magnetic tunnel junction element MTJ3 and the connection wiring 110 and between the fourth magnetic tunnel junction element MTJ4 and the connection wiring 110, a via having the same metal level as that of the (2-2)nd via 122b may be omitted.

Each of a metal level at which the connection wiring 110 is disposed and a metal level at which a via (or wiring) omitted between the third magnetic tunnel junction element MTJ 3 and the connection wiring 110 and between the fourth magnetic tunnel junction elements MTJ3 and MTJ4 and the connection wiring 110 is disposed may vary according to a design of the magnetic memory device.

The first to third lower wiring structures 220l, 230l, and 240l may be spaced apart from each other in the horizontal direction. Each of the first to third lower wiring structures 220l, 230l, and 240l may connect the substrate 100 and the connection wiring 110 to each other.

The first lower wiring structure 220l may include a (1-2)nd via 112b. The second lower wiring structure 230l may include a (1-3)rd via 112c. The third lower wiring structure 240l may include a (1-4)th via 112d. Each of the (1-2)nd to (1-4)th vias 112b, 112c, and 112d may connect each of the second impurity areas (not shown) between the second to fourth cell transistors CT21, CT22, CT31, CT32, CT41, and CT42 to the connection wiring 110. The (1-1)st to (1-4)th vias 112a, 112b, 112c, and 112d may be positioned at the same vertical level from the substrate 100.

The first to third upper wiring structures 220u, 230u, and 240u may be formed on the connection wiring 110. The first to third upper wiring structures 220u, 230u, and 240u may be spaced apart from each other in the horizontal direction. Each of the first to third upper wiring structures 220u, 230u, and 240u may be connected to each of the second to fourth magnetic tunnel junction elements MTJ2, MTJ3, and MTJ4.

The first upper wiring structure 220u may be disposed between the connection wiring 110 and the second magnetic tunnel junction element MTJ2. The first upper wiring structure 220u may connect the connection wiring 110 and the second magnetic tunnel junction element MTJ2 to each other. The first upper wiring structure 220u may include a (2-2)nd via 122b, a (2-2)nd wiring 124b, a (3-2)nd via 132b, a (3-2)nd wiring 134b, a (4-2)nd via 142b, a second landing pad LP2, and a second lower electrode contact BEC2 which are sequentially stacked on the connection wiring 110. The (2-2)nd via 122b may connect the connection wiring 110 and the (2-2)nd wiring 124b to each other. The (3-2)nd via 132b may connect the (2-2)nd wiring 124b and the (3-2)nd wiring 134b to each other. The (4-2)nd via 142b may connect the (3-2)nd wiring 134b and the second landing pad LP2 to each other. The second lower electrode contact BEC2 may connect the second landing pad LP2 and the second magnetic junction element MTJ2 to each other.

The second upper wiring structure 230u may be disposed between the connection wiring 110 and the third magnetic tunnel junction element MTJ3. The second upper wiring structure 230u may be spaced apart from the connection wiring 110 and may be connected to the third magnetic tunnel junction element MTJ3. The second upper wiring structure 230u may include a (2-3)rd wiring 124c, a (3-3)rd via 132c, a (3-3)rd wiring 134c, a (4-3)rd via 142c, a third landing pad LP3, and a third lower electrode contact BEC3 which are sequentially stacked on the connection wiring 110. The (2-3)rd wiring 124c may be spaced apart from the connection wiring 110. The (2-3)rd wiring 124c may not be in direct contact with the connection wiring 110. The (3-3)rd via 132c may connect the (2-3)rd wiring 124c and the (3-3)rd wiring 134c. The (4-3)rd via 142c may connect the (3-3)rd wiring 134c and the third landing pad LP3 to each other. The third lower electrode contact BEC3 may connect the third landing pad LP3 and the third magnetic junction element MTJ3 to each other.

The third upper wiring structure 240u may be disposed between the connection wiring 110 and the fourth magnetic tunnel junction element MTJ4. The third upper wiring structure 240u may be spaced apart from the connection wiring 110 and may be connected to the fourth magnetic tunnel junction element MTJ4. The third upper wiring structure 240u may include a (2-4)th wiring 124d, a (3-4)th via 132d, a (3-4)th wiring 134d, a (4-4)th via 142d, a fourth landing pad LP4, and a fourth lower electrode contact BEC4, which are sequentially stacked on the connection wiring 110. The (2-4)th wiring 124d may be spaced apart from the connection wiring 110. The (2-4)th wiring 124d may not be in direct contact with the connection wiring 110. The (3-4)th via 132d may connect the (2-4)th wiring 124d and the third-fourth wiring 134d to each other. The (4-4)th via 142d may connect the (3-4)th wiring 134d and the fourth landing pad LP4 to each other. The fourth lower electrode contact BEC4 may connect the fourth landing pad LP4 and the fourth magnetic junction element MTJ4 to each other.

The (2-1)st via 122a and the (2-2)nd via 122b may be positioned at the same vertical level from the substrate 100. The (2-1)st to (2-4)th wirings 124a, 124b, 124c, and 124d may be positioned at the same vertical level from the substrate 100. The (3-1)st to (3-4)th vias 132a, 132b, 132c, and 132d may be positioned at the same vertical level from the substrate 100. The (3-1)st to (3-4)th wirings 134a, 134b, 134c, and 134d may be positioned at the same vertical level from the substrate 100. The (4-1)st to (4-4)th vias 142a, 142b, 142c, and 142d may be positioned at the same vertical level from the substrate 100. The first to fourth landing pads LP1, LP2, LP3, and LP4 may be positioned at the same vertical level from the substrate 100. The first to fourth lower electrode contacts BEC1, BEC2, BEC3, and BEC4 may be positioned at the same vertical level from the substrate 100.

Each of the second to fourth lower electrodes BE2, BE3, and BE4 may be formed on each of the second to fourth lower electrode contacts BEC2, BEC3, and BEC4. Each of the second to fourth magnetic tunnel junction elements MTJ2, MTJ3, and MTJ4 may be formed on each of the second to fourth lower electrodes BE2, BE3, and BE4. Each of the second to fourth intermediate electrodes ME2, ME3, and ME4 may be formed on each of the second to fourth magnetic tunnel junction elements MTJ2, MTJ3, and MTJ4. Each of the second to fourth upper electrodes TE2, TE3, and TE4 may be formed on each of the second to fourth intermediate electrodes ME2, ME3, and ME4. Each of the second to fourth upper electrodes TE2, TE3, and TE4 may be connected to each of the second to fourth magnetic tunnel junction elements MTJ2, MTJ3, and MTJ4. The first to fourth upper electrodes TE1, TE2, TE3, and TE4 may be positioned at the same vertical level from the substrate 100.

Each of the second to fourth lower electrodes BE2, BE3, and BE4 may independently or concurrently include a metal such as titanium, tantalum, or the like, or a metal nitride such as titanium nitride, tantalum nitride, or the like. Each of the second to fourth intermediate electrodes ME2, ME3, and ME4 may independently or concurrently include at least one of a metal such as titanium or tantalum or a metal nitride such as titanium nitride and/or tantalum nitride. Each of the second to fourth upper electrodes TE2, TE3, and TE4 may include at least one of a metal such as titanium, tantalum, or the like, or a metal nitride such as titanium nitride, tantalum nitride, or the like. Alternatively or additionally, each of the second to fourth upper electrodes TE2, TE3, and TE4 may independently or concurrently include one or more of tungsten, copper, platinum, nickel, silver, gold, or the like.

The second bit line BL2 may be formed on the second to fourth upper electrodes TE2, TE3, and TE4. The second bit line BL2 may be connected to the second to fourth upper electrodes TE2, TE3, and TE4. The first and second bit lines BL1 and BL2 may be positioned at the same vertical level from the substrate 100.

The second magnetic tunnel junction element MTJ2 may be electrically connected to the second to fourth cell transistors CT21, CT22, CT31, CT32, CT41, and CT42 via the first upper wiring structure 220u, the connection wiring 110, and the first to third lower wiring structures 220l, 230l, and 240l, and may be electrically connected to the second bit line BL2 via the second upper electrode TE2.

Each of the vias and the wirings of each of the wiring structure 210, the first to third lower wiring structures 220l, 230l, and 240l, and the first to third upper wiring structures 220u, 230u, and 240u may include at least one of a metal (e.g., copper) and a conductive metal nitride (e.g., titanium nitride, tantalum nitride, and/or tungsten nitride).

Each of the first to fourth landing pads LP1, LP2, LP3, and LP4 may include, for example, at least one of a doped semiconductor material (e.g., doped silicon), a metal (e.g., tungsten, titanium, and/or tantalum), a metal-semiconductor compound (e.g., metal silicide), and a conductive metal nitride (e.g., titanium nitride, tantalum nitride, and/or tungsten nitride).

Although not shown in detail, each of the first to fourth lower electrode contacts BEC1, BEC2, BEC3, and BEC4 may include a barrier pattern (not shown) and/or a conductive pattern (not shown). The barrier pattern (not shown) may include a metal nitride such as tungsten nitride, tantalum nitride, titanium nitride, and the like, and/or a metal such as tantalum, titanium, and the like, and the conductive pattern (not shown) may include a conductive material such as copper, etc.

The first via structure V1 and the second via structure V2 may be spaced apart from each other in the second horizontal direction Y and may be disposed between the memory cell MC and the OTP cell OTPC.

The first via structure V1 may be disposed on one side in the second horizontal direction Y of the switching element SW. The first via structure V1 may be disposed adjacent to the first magnetic tunnel junction element MTJ1. The first via structure V1 may be disposed between the first magnetic tunnel junction element MTJ1 and the switching element SW.

The second via structure V2 may be disposed on the other side in the second horizontal direction Y of the switching element SW. The second via structure V2 may be disposed adjacent to the second magnetic tunnel junction element MTJ2. The second via structure V2 may be disposed between the second magnetic tunnel junction element MTJ2 and the switching element SW.

The first bit line BL1 and the second bit line BL2 may be disposed on the first via structure V1 and the second via structure V2, respectively. The first bit line BL1 and the second bit line BL2 may be spaced apart from each other in the second horizontal direction Y while being respectively disposed on the first via structure V1 and the second via structure V2. For example, the bit line BL may be physically discontinuous between the first and second via structures V1 and V2.

When the write operation of the OTP cell OTPC is performed, the peripheral circuit may control the switching element SW to electrically disconnect the first and second bit lines BL1 and BL2 from each other via the first and second via structures V1 and V2.

When a write operation of the memory cell MC is performed, the peripheral circuit may control the switching element SW to electrically connect the first and second bit lines BL1 and BL2 to each other via the first and second via structures V1 and V2. When a write operation of the memory cell MC is performed, the peripheral circuit may turn on the switching element SW to form an electrical path P1 composed of the first bit line BL1, the first via structure V1, the switching element SW, the second via structure V2, and the second bit line BL2. Accordingly, the switching element SW may electrically connect the first and second bit lines BL1 and BL2 to each other through the first and second via structures V1 and V2.

In this case, one end of the switching element SW may be connected to the first bit line BL1 via the first via structure V1, and another end of the switching element SW may be connected to the second bit line BL2 via the second via structure V2. The third impurity area 102e of the switching element SW may be connected to the first bit line BL1 through the first via structure V1. The fourth impurity area 102f of the switching element SW may be connected to the second bit line BL2 via the second via structure V2.

At least a portion of each of the first via structure V1 and the second via structure V2 may be disposed in the insulating film 101, and another portion of each of the first via structure V1 and the second via structure V2 may be disposed on the insulating film 101.

The first via structure V1 may include a 1e-th via 112e, a 1e-th wiring 114e, a 2e-th via 122e, a 2e-th wiring 124e, a 3e-th via 132e, a 3e-th wiring 134e, a 4e-th via 142e, a 4e-th wiring 144e, and a 5e-th via 154e sequentially stacked on the substrate 100.

The 1e-th via 112e may be connected to the third impurity area 102e of the switching element SW. The 2e-th via 122e may connect the 1e-th wiring 114e and the 2e-th wiring 124e. The 3e-th via 132e may connect the 2e-th wiring 124e and the 3e-th wiring 134e to each other. The 4e-th via 142e may connect the 3e-th wiring 134e and the 4e-th wiring 144e to each other. The 5e-th via 154e may connect the 4e-th wiring 144e to the first bit line BL1.

The second via structure V2 may include a 1f-th via 112f, a 1f-th wiring 114f, a 2f-th via 122f, a 2f-th wiring 124f, a 3f-th via 132f, a 3f-th wiring 134f, a 4f-th via 142f, a 4f-th wiring 144f, and a 5f-th via 154f sequentially stacked on the substrate 100.

The 1f-th via 112f may be connected to the fourth impurity area 102f of the switching element SW. The 2f-th via 122f may connect the 1f-th wiring 114f and the 2f-th wiring 124f. The 3f-th via 132f may connect the 2f-th wiring 124f and the 3f-th wiring 134f to each other. The 4f-th via 142f may connect the 3f-th wiring 134f to the 4f-th wiring 144f. The 5f-th via 154f may connect the 4f-th wiring 144f to the second bit line BL2.

The 1e-th and 1f-th vias 112e and 112f may be positioned at the same vertical level from the substrate 100 as that of each of the (1-1)st to 1-4-th vias 112a, 112b, 112c, and 112d. The 1e-th and 1f-th wirings 114e and 114f may be positioned at the same vertical level from the substrate 100 as that of each of the (1-1)st wiring 114a and the connection wiring 110.

The 2e-th and 2f-th vias 122e and 122f may be positioned at the same vertical level from the substrate 100 as that of each of the 2-1-th via 122a and the 2-2-th via 122b. The 2e-th and 2f-th wirings 124e and 124f may be positioned at the same vertical level from the substrate 100 as that of each of the 2-1-th to 2-4-th wirings 124a, 124b, 124c, and 124d.

The 3e-th and 3f-th vias 132e and 132f may be positioned at the same vertical level from the substrate 100 as that of each of the 3-1-th to 3-4-th vias 132a, 132b, 132c, and 132d. The 3e-th and 3f-th wirings 134e and 134f may be positioned at the same vertical level from the substrate 100 as that of each of the 3-1-th to 3-4-th wirings 134a, 134b, 134c, and 134d.

The 4e-th and 4f-th vias 142e and 142f may be positioned at the same vertical level from the substrate 100 as that of each of the 4-1-th to 4-4-th vias 142a, 142b, 142c, and 142d. The 4e-th and 4f-th wirings 144e and 144f may be positioned at the same vertical level from the substrate 100 as that of each of the first to fourth landing pads LP1, LP2, LP3, and LP4.

The upper surfaces of the 5e-th and 5f-th vias 154e and 154f may be positioned at the same vertical level from the substrate 100 as that of each of the upper surfaces of the first to fourth magnetic tunnel junction elements MTJ1, MTJ2, MTJ3, and MTJ4. Each of the 5e-th and 5f-th vias 154e and 154f may at least partially extend into a barrier layer BR, a first mold insulating layer M1, a capping layer EN, and a second mold insulating layer M2, which will be described later. Each of the 5e-th and 5f-th vias 154e and 154f may extend through at least a portion of each of the barrier layer BR, the first mold insulating layer M1, the capping layer EN, and the second mold insulating layer M2 which will be described later, in the third direction Z.

Each of the vias and the wirings of the first via structure V1 and the second via structure V2 may independently or concurrently include at least one of a metal (e.g., copper) and a conductive metal nitride (e.g., one or more of titanium nitride, tantalum nitride, or tungsten nitride).

The magnetic memory device according to some example embodiments may further include the barrier film BR, the first mold insulating film M1, the capping film EN, and the second mold insulating film M2.

The barrier layer BR may be formed on the upper surfaces of the insulating film 101 of the memory cell array 11, the OTP cell array 12, and the switching element array 13. The barrier layer BR may be formed on the first landing pad LP1, the 4e-th wiring 144e, the 4f-th wiring 144f, and the second to fourth landing pads LP2, LP3, and LP4.

The barrier layer BR may include at least one of carbon (C), nitrogen (N), and silicon (Si). The barrier layer BR may include a silicon (Si)-based material including at least one of carbon (C) and nitrogen (N). For example, the barrier layer BR may include SiCN.

The first mold insulating layer M1 may be formed on the insulating film 101 of the memory cell array 11, the OTP cell array 12, and the switching element array 13. The first mold insulating layer M1 may be formed on the barrier layer BR of the memory cell array 11, the OTP cell array 12, and the switching element array 13. The first mold insulating layer M1 may include an oxide such as silicon oxide.

The first to fourth lower electrode contacts BEC1, BEC2, BEC3, and BEC4 may be formed in the barrier film BR and the first mold insulating film M1. The first to fourth lower electrode contacts BEC1, BEC2, BEC3, and BEC4 may extend through the barrier film BR and the first mold insulating film M1. Each of sidewalls of the first to fourth lower electrode contacts BEC1, BEC2, BEC3, and BEC4 may be surrounded with the barrier film BR and the first mold insulating film M1.

An upper surface of the first mold insulating layer M1 may be recessed. That is, a thickness of a portion of the first mold insulating film M1 adjacent to the first to fourth lower electrode contacts BEC1, BEC2, BEC3, and BEC4 may be greater than a thickness of a portion of the first mold insulating film M1 far away from the first to fourth lower electrode contacts BEC1, BEC2, BEC3, and BEC4.

The capping layer EN may be formed on the first mold insulating layer M1 of the memory cell array 11, the OTP cell array 12, and the switching element array 13 and along a sidewall of the memory structure MST. The capping layer EN may be conformally formed on the surfaces of the first mold insulating layer M1 and the memory structure MST. The capping layer EN may have a substantially uniform thickness.

The capping film EN may contact the sidewall of the memory structure MST to protect the memory structure MST. The capping film EN may be disposed on the sidewalls of the first to fourth lower electrodes BE1, BE2, BE3, and BE4. The capping film EN may be disposed on the sidewalls of the first to fourth intermediate electrodes ME1, ME2, ME3, and ME4. The capping film EN may be disposed on the sidewalls of the first to fourth upper electrodes TE1, TE2, TE3 and TE4. The upper surface of the capping layer EN may have a recessed shape like the upper surface of the first mold insulating layer M1. The capping layer EN may include silicon nitride or silicon oxynitride.

The second mold insulating layer M2 may be formed on the capping layer EN of the memory cell array 11, the OTP cell array 12, and the switching element array 13. The second mold insulating layer M2 may be disposed on sidewalls of the memory structure MST and the capping layer EN. The second mold insulating layer M2 may fill or at least partially fill a space between the memory structures MST.

The second mold insulating layer M2 may include an oxide such as silicon oxide. For example, the first mold insulating film M1 may include an oxide such as LK (low-k). However, the second mold insulating layer M2 may include a high density plasma-chemical vapor deposition (HDP-CVD) oxide. That is, the first and second mold insulating films M1 and M2 may include different materials. However, example embodiments are not limited thereto.

In the second horizontal direction Y in which the first bit line BL1 and the second bit line BL2 extend, the number of switching elements arranged between the first bit line BL1 and the second bit line BL2 may be one. However, the technical idea of example embodiments are not limited thereto.

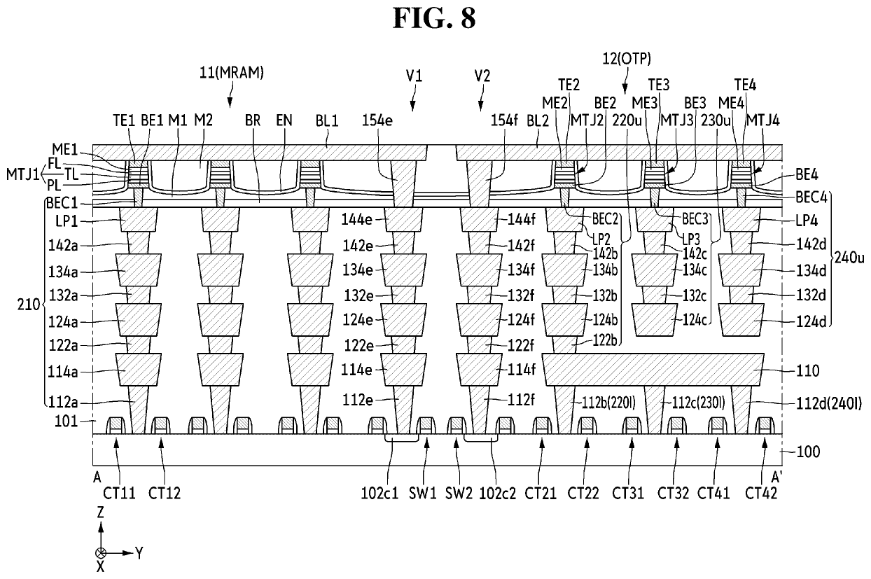

FIG. 8 is an example cross-sectional view of a magnetic memory device according to some example embodiments. For convenience of description, contents duplicate with those described above with reference to FIGS. 1 to 7 will be briefly described or the descriptions thereof are omitted.

Referring to FIG. 8, the magnetic memory device according to some example embodiments may include first and second switching elements SW1 and SW2 disposed between the first and second via structures V1 and V2. That is, in the second horizontal direction Y in which the first bit line BL1 and the second bit line BL2 extend, the number of switching elements arranged between the first bit line BL1 and the second bit line BL2 may be two or more.

One end of the first switching element SW1 may be connected to the first bit line BL1 through the first via structure V1, and one end of the second switching element SW2 may be connected to the second bit line BL2 through the second via structure V2.

The first via structure V1 may be connected to an impurity area 102c1 of the first switching element SW1. The second via structure V2 may be connected to an impurity area 102c2 of the second switching element SW2.

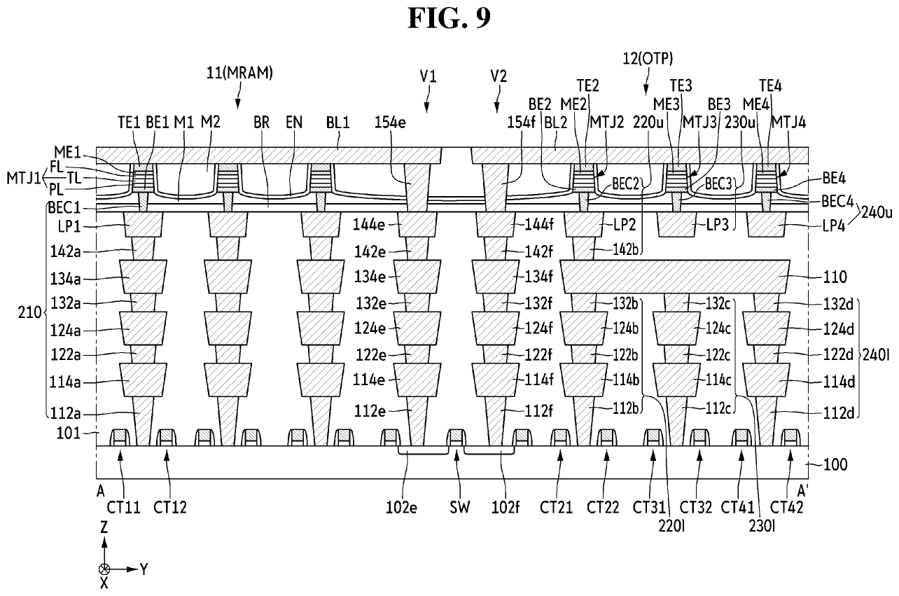

FIGS. 9 to 11 are example cross-sectional views of a magnetic memory device according to some example embodiments. For convenience of description, contents duplicate with those described above with reference to FIGS. 1 to 8 will be briefly described or the descriptions thereof are omitted. For convenience of illustration, the source line SL of FIG. 2 is omitted from FIGS. 9 to 11.

Referring to FIG. 9, the connection wiring 110 of the magnetic memory device according to some example embodiments may be positioned at the same vertical level from the substrate 100 as that of the (3-1)st wiring 134a (see FIG. 7). That is, the wirings disposed at the same metal level as that of the (3-1)st wiring 134a (see FIG. 7) and respectively disposed under the second to fourth magnetic tunnel junction elements MT2, MTJ3, and MT4 may be directly connected to each other.

Between the third magnetic tunnel junction element MTJ3 and the connection wiring 110 and between the fourth magnetic tunnel junction element MTJ4 and the connection wiring 110, a via having the same metal level as that of the (4-2)nd via 142b may be omitted.

The first lower wiring structure 220l may include a (1-2)nd via 112b, a (1-2)nd wiring 114b, a (2-2)nd via 122b, a (2-2)nd wiring 124b, and a (3-2)nd via 132b which are sequentially stacked on the substrate 100. The second lower wiring structure 230l may include a (1-3)rd via 112c, a (1-3)rd wiring 114c, a (2-3)rd via 122c, a (2-3)rd wiring 124c, and a (3-3)rd via 132c sequentially stacked on the substrate 100. The third lower wiring structure 240l may include a (1-4)th via 112d, a (1-4)th wiring 114d, a (2-4)th via 122d, a (2-4)th wiring 124d, and a (3-4)th via 132d, which are sequentially stacked on the substrate 100. Each of the (2-2)nd to (2-4)th vias 122b, 122c, and 122d may connect each of the (1-2)nd to (1-4)th wirings 114b, 114c, and 114d to each of the (2-2)nd to (2-4)th wirings 124b, 124c, and 124d. Each of the (3-2)nd to (3-4)th vias 132b, 132c, and 132d may connect each of the (2-2)nd to (2-4)th wirings 124b, 124c, and 124d to the connection wiring 110.

The first upper wiring structure 220u may include a (4-2)nd via 142b, a second landing pad LP2, and a second lower electrode contact BEC2, which are sequentially stacked on the connection wiring 110. The (4-2)nd via 142b may connect the connection wiring 110 and the second landing pad LP2 to each other. The second upper wiring structure 230u may include a third landing pad LP3 and a third lower electrode contact BEC3, which are sequentially stacked on the connection wiring 110. The third landing pad LP 3 may be spaced apart from the connection wiring 110. The third landing pad LP 3 may not be in direct contact with the connection wiring 110. The third upper wiring structure 240u may include a fourth landing pad LP4 and a fourth lower electrode contact BEC4 sequentially stacked on the connection wiring 110. The fourth landing pad LP4 may be spaced apart from the connection wiring 110. The fourth landing pad LP 4 may not be in direct contact with the connection wiring 110.

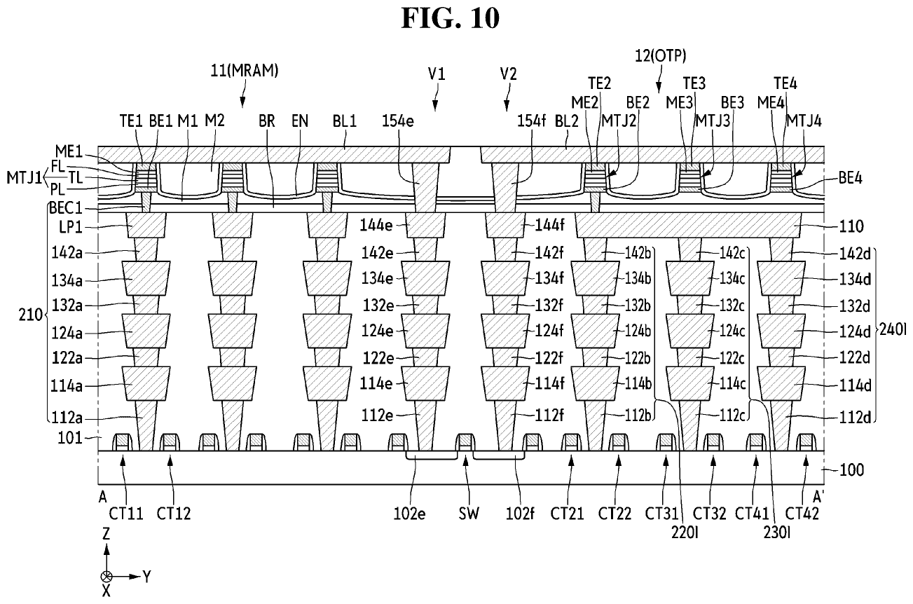

Referring to FIG. 10, the connection wiring 110 of the magnetic memory device according to some example embodiments may be positioned at the same vertical level from the substrate 100 as that of the first landing pad LP1 (see FIG. 7). That is, the wirings disposed at the same metal level as that of the first landing pad LP1 (see FIG. 7) and respectively disposed under the second to fourth magnetic tunnel junction elements MT2, MTJ3, and MT4 may be directly connected to each other.

Between the third magnetic tunnel junction element MTJ3 and the connection wiring 110 and between the fourth magnetic tunnel junction element MTJ4 and the connection wiring 110, a via having the same metal level as that of the second lower electrode contact BEC2 may be omitted.

The first lower wiring structure 220l may include a (1-2)nd via 112b, a (1-2)nd wiring 114b, a (2-2)nd via 122b, a (2-2)nd wiring 124b, a (3-2)nd via 132b, a (3-2)nd wiring 134b, and a (4-2)nd via 142b, which are sequentially stacked on the substrate 100. The second lower wiring structure 230l may include a (1-3)rd via 112c, a (1-3)rd wiring 114c, a (2-3)rd via 122c, a (2-3)rd wiring 124c, a (3-3)rd via 132c, a (3-3)rd wiring 134c, and a (4-3)rd via 142c, which are sequentially stacked on the substrate 100. The third lower wiring structure 240l may include a (1-4)th via 112d, a (1-4)th wiring 114d, a (2-4)th via 122d, a (2-4)th wiring 124d, a (3-4)th via 132d, a (3-4)th wiring 134d, and a (4-4)th via 142d, which are sequentially stacked on the substrate 100. Each of the (4-2)nd to (4-4)th vias 142b, 142c, and 142d may connect each of the (3-2)nd to (3-4)th wirings 134b, 134c, and 134d to the connection wiring 110.

The first upper wiring structure 220u may include the second lower electrode BE2. The second lower electrode contact BEC2 may connect the connection wiring 110 and the second magnetic tunnel junction element MTJ2 to each other. The third magnetic tunnel junction element MTJ3 and the fourth magnetic tunnel junction element MTJ4 may be spaced apart from the connection wiring 110. The third magnetic tunnel junction element MTJ 3 and the fourth magnetic tunnel junction element MTJ 4 may not be in direct contact with the connection wiring 110.

The OTP cell OTPC may include second to fourth cell transistors CT21, CT22, CT31, CT32, CT41, and CT42, a connection wiring 110, first to third lower wiring structures 220l, 230l, and 240l, a first upper wiring structure 220u, second to fourth magnetic tunnel junction elements MTJ2, MTJ3, and MTJ4, and second to fourth upper electrodes TE2, TE3, and TE4.

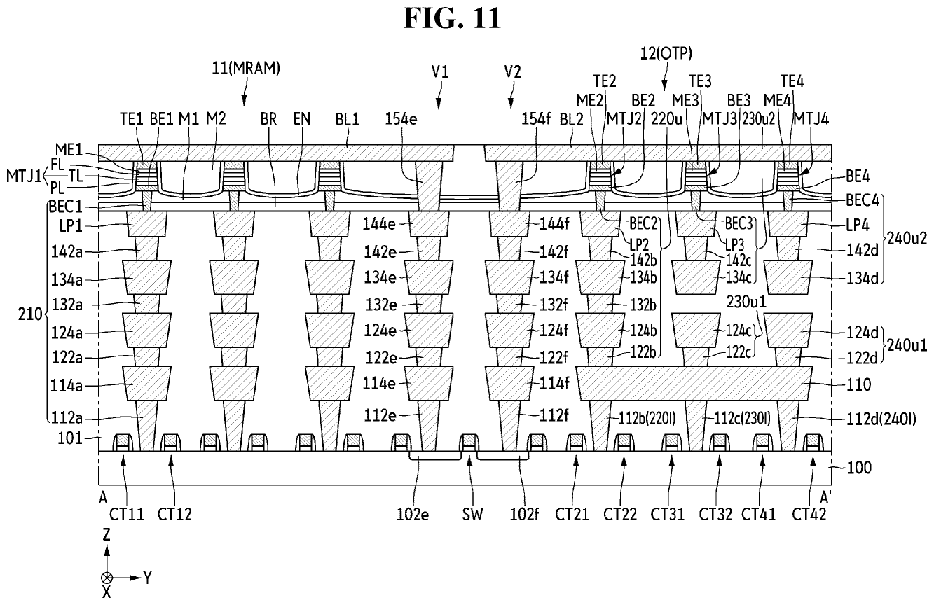

Referring to FIG. 11, between each of the third and fourth magnetic tunnel junction elements MTJ3 and MTJ4 and the connection wiring 110 of the magnetic memory device according to some example embodiments, a via having the same metal level as that of a via not in direct contact with the connection wiring 110 may be omitted. For example, a via having the same metal level as that of the (3-2)nd via 132b may be omitted between the third magnetic tunnel junction element MTJ3 and the connection wiring 110 and between the fourth magnetic tunnel junction elements MTJ3 and MTJ4 and the connection wiring 110.

A first sub-wiring structure 230u1 and a second sub-wiring structure 230u2 may be disposed between the connection wiring 110 and the third magnetic tunnel junction element MTJ3. The first sub-wiring structure 230u1 may be connected to the connection wiring 110. The second sub-wiring structure 230u2 may be connected to the third magnetic tunnel junction element MTJ3. The first sub-wiring structure 230u1 and the second sub-wiring structure 230u2 may be spaced apart from each other in the vertical direction. The first sub-wiring structure 230u1 and the second sub-wiring structure 230u2 may not be in direct contact with each other.

The first sub-wiring structure 230u1 may include a (2-3)rd via 122c and a (2-3)rd wiring 124c sequentially stacked on the connection wiring 110. The second sub-wiring structure 230u2 may include a third lower electrode contact BEC3, a third landing pad LP3, a (4-3)rd via 142c, and a (3-3)rd wiring 134c which are sequentially stacked and are disposed under the third magnetic tunnel junction element MTJ3. The (2-3)rd wiring 124c and the (3-3)rd wiring 134c may be spaced apart from each other. The (2-3)rd wiring 124c and the (3-3)rd wiring 134c may not be in direct contact with each other.

A third sub-wiring structure 240u1 and a fourth sub-wiring structure 240u2 may be disposed between the connection wiring 110 and the fourth magnetic tunnel junction element MTJ4. The third sub-wiring structure 240u1 may be connected to the connection wiring 110. The fourth sub-wiring structure 240u2 may be connected to the fourth magnetic tunnel junction element MTJ4. The third sub-wiring structure 240u1 and the fourth sub-wiring structure 240u2 may be spaced apart from each other in the vertical direction. The third sub-wiring structure 240u1 and the fourth sub-wiring structure 240u2 may not be in direct contact with each other.

The third sub-wiring structure 240u1 may include a (2-4)th via 122d and a (2-4)th wiring 124d sequentially stacked on the connection wiring 110. The fourth sub-wiring structure 240u2 may include a fourth lower electrode contact BEC4, a fourth landing pad LP4, a (4-4)th via 142d, and a (3-4)th wiring 134d which are sequentially stacked and are disposed under the fourth magnetic tunnel junction element MTJ4. The (2-4)th wiring 124d and the (3-4)th wiring 134d may be spaced apart from each other. The (2-4)th wiring 124d and the (3-4)th wiring 134d may not be in direct contact with each other.

FIG. 12 is a diagram for illustrating a cell area and a peripheral circuit area of a magnetic memory device according to some example embodiments. FIG. 13 is an enlarged view for illustrating an area S of FIG. 12. For convenience of description, contents duplicate with those as described above with reference to FIGS. 1 to 11 will be briefly described or the descriptions thereof are omitted.

Referring to FIG. 12, the magnetic memory device according to some example embodiments may include a cell area CELL and a peripheral circuit area CPR. The memory cell array 11, the OTP cell array 12, and the switching element array 13 as described above may be disposed in the cell area CELL. The above-described peripheral circuit may be disposed in the peripheral circuit area CPR.

The cell area CELL and the peripheral circuit area CPR may be adjacent to each other in the first direction DR1 and the second direction DR2 intersecting each other. The cell areas CELL may be spaced apart from each other in the first direction DR1 and the second direction DR 2 while the peripheral circuit area CPR is interposed therebetween. The first direction DR1 may be a direction in which the above-described bit line BL extends. The second direction DR2 may be a direction perpendicular to the first direction DR1.

Referring to FIG. 13, the peripheral circuit PERI may include the row selection circuit 20, the column selection circuit 30, the write driver 40, and the sensing circuit 50. Although not shown in detail, the peripheral circuit may further include the source line driver 60, the input/output circuit 70, and the control logic 80 described with reference to FIG. 1.

The row selection circuit 20 may include a row decoder 21, and the column selection circuit 30 may include a column decoder 31.

The contents of the row selection circuit 20, the column selection circuit 30, the write driver 40, and the sensing circuit 50 of FIG. 13 may be similarly applied to the contents of the row selection circuit 20, the column selection circuit 30, the write driver 40, and the sensing circuit 50 as described with reference to FIG. 1.

The row decoder 21 may select a word line connected to the memory cell MC (see FIG. 2) and the OTP cell OTPC (see FIG. 2) based on the row address R_ADDR (see FIG. 1). The column decoder 31 may select a bit line and/or a source line connected to the memory cell MC of FIG. 2 and the OTP cell OTPC of FIG. 2 based on the column address C_ADDR of FIG. 1.

The write driver 40 may drive a write voltage to a memory cell (MC of FIG. 2) and an OTP cell (OTPC of FIG. 2) selected by the row decoder 21 and the column decoder 31. The sensing circuit 50 may be used to determine a value of data stored in each of the memory cell (MC of FIG. 2) and the OTP cell (OTPC of FIG. 2).

In the first direction DR 1, the peripheral circuit PERI may be disposed closer to the OTP cell array 12 than to the memory cell array 11. That is, the peripheral circuit area CPR may be connected to the bit line that is closer to the OTP cell array 12 than to the memory cell array 11. The OTP cell array 12 may be disposed between the memory cell array 11 and the peripheral circuit area CPR in the first direction DR1.

For example, in the first direction DR1, the column decoder 31 may be disposed closer to the OTP cell array 12 than to the memory cell array 11. In this case, the OTP cell array 12 may be disposed between the memory cell array 11 and the column decoder 31.

Although FIG. 13 illustrates that the column decoder 31 is closer to the cell area CELL than the row decoder 21 is, example embodiments are not limited thereto. In some example embodiments, the row decoder 21 may be disposed closer to the cell area CELL than the column decoder 31 may be.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although some example embodiments have been described above with reference to the accompanying drawings, the inventive concepts may not be limited to embodiments and may be implemented in various different forms. Those of ordinary skill in the technical field to which inventive concepts belongs will be able to appreciate that inventive concepts may be implemented in other specific forms without changing the technical idea or essential features of inventive concepts. Therefore, it should be understood that embodiments as described above are not restrictive but illustrative in all respects. Additionally, example embodiments are not necessarily mutually exclusive with one another. For example, some example embodiments may include one or more features described with reference to one or more figures, and may also include one or more other features described with reference to one or more other figures.

What is claimed is:

1. A magnetic memory device comprising:
a memory cell including a first magnetic tunnel junction element;
a One-Time-Programmable (OTP) cell including a second magnetic tunnel junction element;
a switching element between a first bit line connected to the memory cell and a second bit line connected to the OTP cell; and
a peripheral circuit configured to control the switching element to disconnect the first bit line and the second bit line from each other in response to a write voltage being applied to the OTP cell.

2. The magnetic memory device of claim 1, wherein in response to the write voltage being applied to the OTP cell, the peripheral circuit is configured to control the write voltage not to be applied to the memory cell.

3. The magnetic memory device of claim 1, further comprising:
a first via structure on one side of the switching element and adjacent to the first magnetic tunnel junction element; and
a second via structure on another side of the switching element and adjacent to the second magnetic tunnel junction element.

4. The magnetic memory device of claim 3, wherein the first bit line and the second bit line are respectively arranged on the first via structure and the second via structure and are spaced apart from each other.

5. The magnetic memory device of claim 3, wherein
the first via structure is between the first magnetic tunnel junction element and the switching element,
the second via structure is between the second magnetic tunnel junction element and the switching element, and
the first via structure and the second via structure are spaced apart from each other.

6. The magnetic memory device of claim 3, wherein the switching element includes a plurality of switching elements between the first via structure and the second via structure.

7. The magnetic memory device of claim 3, wherein in response to the write voltage being applied to the memory cell, the peripheral circuit is configured to control the switching element to electrically connect the first bit line and the second bit line to each other by using the first via structure and the second via structure.

8. The magnetic memory device of claim 7, wherein
one end of the switching element is electrically connected to the first bit line through the first via structure, and
another end of the switching element is electrically connected to the second bit line through the second via structure.

9. The magnetic memory device of claim 1, wherein the peripheral circuit is closer to the OTP cell than to the memory cell in a direction in which the first bit line and the second bit line extend.

10. The magnetic memory device of claim 1, wherein the memory cell and the OTP cell share the peripheral circuit with each other.

11. The magnetic memory device of claim 1, wherein the peripheral circuit includes:
a row decoder configured to select a word line connected to the OTP cell based on a row address;
a column decoder configured to select the second bit line connected to the OTP cell based on a column address; and
a write driver configured to apply the write voltage to the OTP cell selected by the row decoder and the column decoder.

12. A magnetic memory device comprising:
a memory cell connected to a first bit line and including a first magnetic tunnel junction element;
a One-Time-Programmable (OTP) cell connected to a second bit line and including a second magnetic tunnel junction element;
a bit line connection transistor between the first bit line and the second bit line in a first direction in which the first bit line and the second bit line extend; and
a peripheral circuit configured to control the bit line connection transistor,
wherein the peripheral circuit is configured to:
control the bit line connection transistor to be turned off in response to a first write voltage being applied to the OTP cell; and
control the bit line connection transistor to be turned on in response to a second write voltage being applied to the memory cell.

13. The magnetic memory device of claim 12, wherein
the OTP cell corresponds to a first word line,
the bit line connection transistor corresponds to a second word line,
the peripheral circuit is further configured to activate a first driving signal driving the first word line and to deactivate a second driving signal driving the second word line in response to the first write voltage or the second write voltage being applied to the OTP cell.

14. The magnetic memory device of claim 12, wherein the peripheral circuit is closer to the OTP cell than to the memory cell in the first direction.

15. The magnetic memory device of claim 12, wherein the OTP cell is between the bit line connection transistor and the peripheral circuit in the first direction.

16. A magnetic memory device comprising a memory cell and a One-Time-Programmable (OTP) cell,
wherein the memory cell includes:
a first magnetic tunnel junction element connected to a first bit line; and
a first cell transistor connecting a first source line and the first magnetic tunnel junction element to each other and connected to a first word line,
wherein the OTP cell includes:
a second magnetic tunnel junction element connected to a second bit line;
a cell array connecting a second source line and the second magnetic tunnel junction element to each other, wherein the cell array includes a second cell transistor, a third cell transistor, and a fourth cell transistor that are connected to a second word line, a third word line, and a fourth word line, respectively;
a switching element between the first bit line and the second bit line in a first direction in which the first bit line and the second bit line extend;
a first via structure on one side of the switching element and adjacent to the memory cell;
a second via structure on another side of the switching element and adjacent to the OTP cell; and
a peripheral circuit closer to the OTP cell than to the memory cell in the first direction,
wherein the peripheral circuit is configured to control the switching element to electrically disconnect the first bit line and the second bit line from each other in response to a first write operation being performed on the OTP cell.

17. The magnetic memory device of claim 16, wherein the peripheral circuit is further configured to control the switching element to be turned on in response to at least one of a second write operation being performed on the memory cell, a first read operation being performed on the memory cell, or a second read operation is performed on the OTP cell.

18. The magnetic memory device of claim 16, wherein the peripheral circuit is further configured to control the switching element to be turned off in response to a write voltage being applied to the OTP cell.

19. The magnetic memory device of claim 18, wherein the peripheral circuit is further configured to control the write voltage not to be applied to the memory cell.

20. The magnetic memory device of claim 16, wherein the peripheral circuit is further configured to select the second word line and not to select the third word line in order to apply a write voltage to the OTP cell.
